(19) United States
(12) Patent Application Publication
(10) Pub. No.: US 2009/0152576 A1
(43) Pub. Date: Jun. 18, 2009

(54) Blue-green light-emitting semiconductor and phosphor for same

(76) Inventors: Soshchin Naum, Changhua City (TW); Wei-Hung Lo, Taipei City (TW); Chi-Ruei Tsai, Taipei City (TW)

Correspondence Address: The Weintraub Group, P.L.C., 28580 Orchard Lake Road, Suite 140, Farmington Hills, MI, 48334, US

(21) Appl. No.: 12/315,670

(22) Filed: Dec. 5, 2008

(30) Foreign Application Priority Data
Dec. 12, 2007 (TW) 096147530

(51) Int. Cl. H01L 33/00; C09K 11/59; C09K 11/79

(52) U.S. Cl. 257/94; 252/301.4 F; 257/E33.028; 257/E33.027

(57) ABSTRACT

A blue-green light emitting semiconductor having an In—Ga—N heterostructure and covered with a light-converting layer formed of a thermosetting polymer layer and an inorganic phosphor having a long wave Stokes radiation displacement characteristic, characterized in that the In—Ga—N semiconductor heterostructure emits light in near ultraviolet region λ=375˜405 nm, the light-converting layer converts the emission λ=375˜405 nm to wavelength λ=505˜515 nm; the wavelength light emitted by the light-converting layer has Stokes displacement 135˜105 nm, color coordinates 0.15<x≦0.22, 0.55<y≦0.60, spectrum curve half-wave width Δλ≦60 nm, and afterglow duration smaller than 100 ns. The invention also discloses a phosphor for use in a blue-green light-emitting semiconductor.

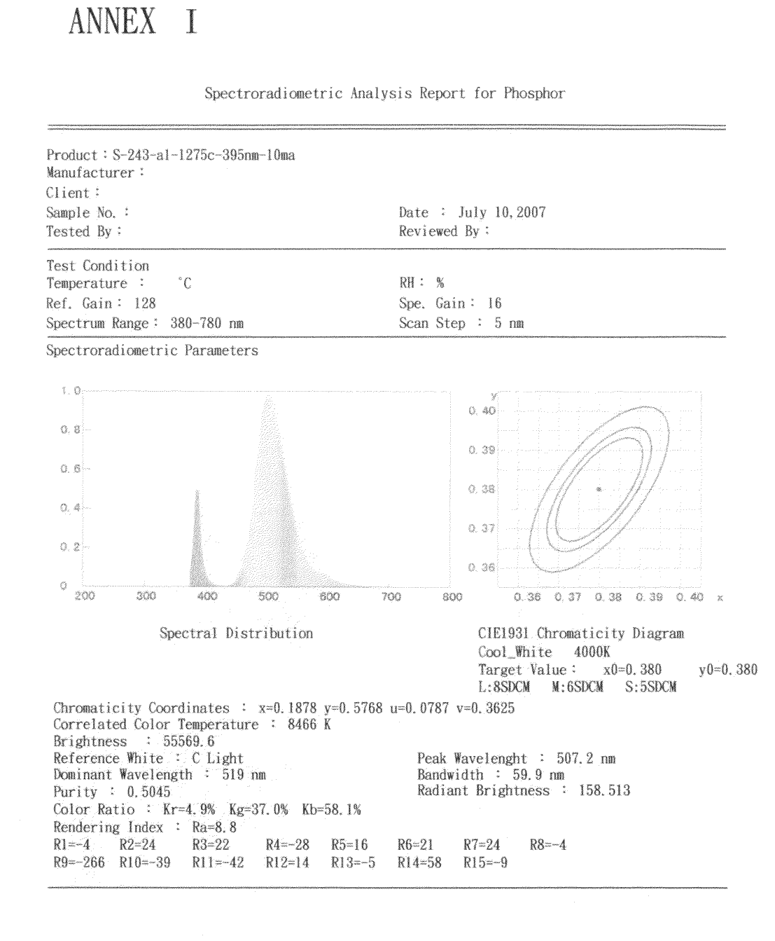

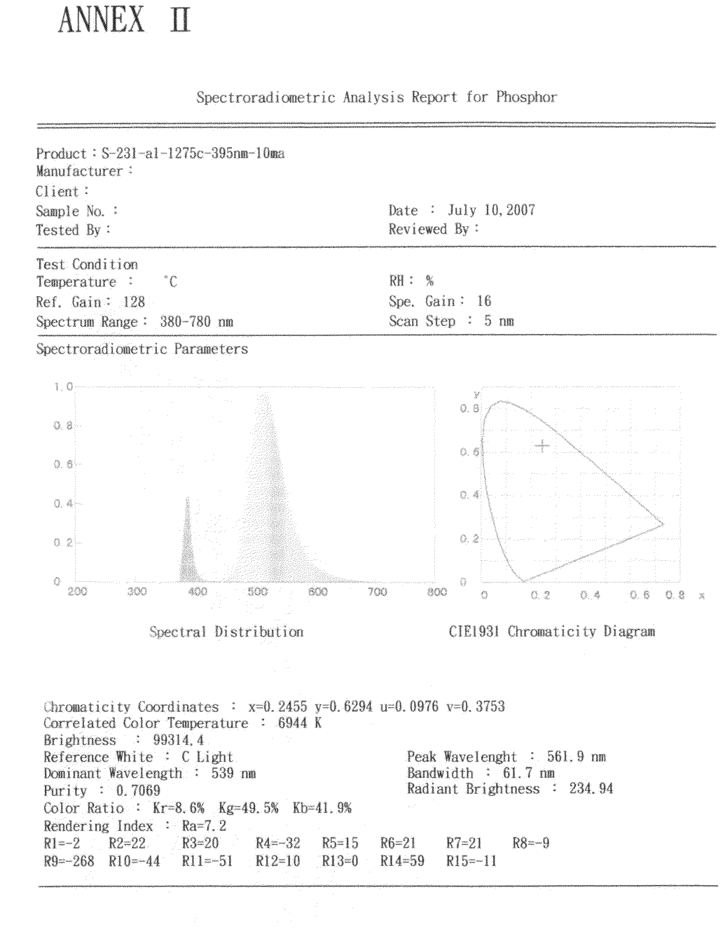

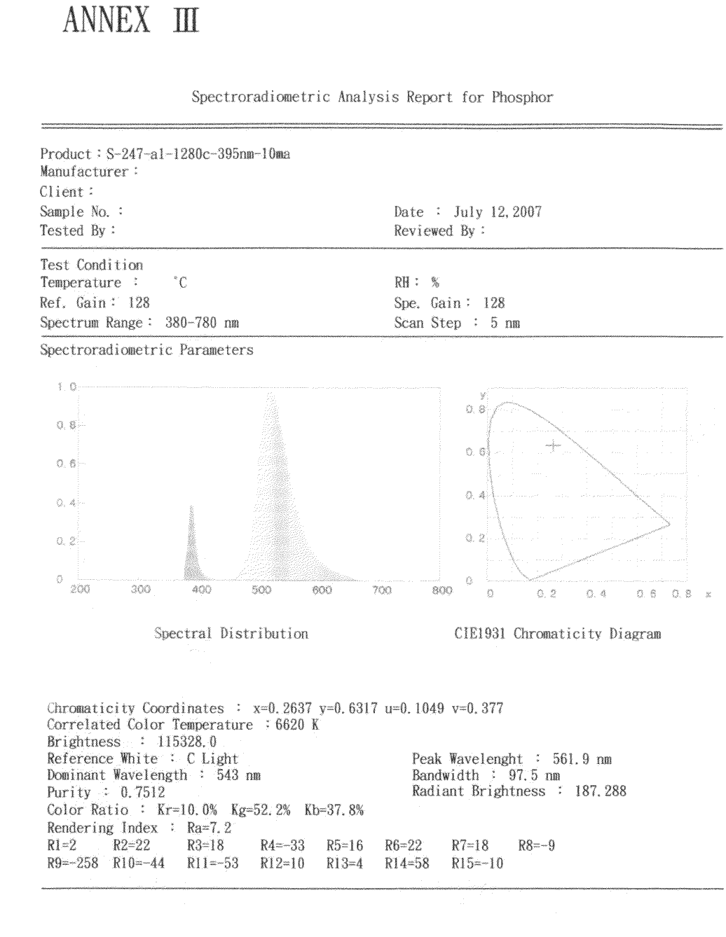

### BACKGROUND OF THE INVENTION

1. Field of the Invention

The present invention relates to semiconductor microelectronics and lighting technology and more particularly, to the fabrication of a blue-green light emitting semiconductor. The phosphor used in this blue-green light emitting semiconductor convertsλ=375˜405 nm ultraviolet light intoλ=505˜515 nm of which the Stokes displacement is 135˜105 nm; the color coordinates is within 0.15<x≦0.22, 0.55<y=0.60; the width of the half wave of the spectrum curve is Δλ≦60 nm; the afterglow duration is smaller than 100 ns.

2. Description of the Related Art

Light emitting semiconductor, more particularly, light emitting diode constructs modern architecture and landscape illumination technology for application to city illumination and luminous design of architecture memorial and natural preservation zone. Industrial application of light technology is the direction of research called “Green Light”. It has a great concern with the creation of high-efficient, safety and cheap light emitting devices. Unfortunately, most of these devices are incandescent or gas-discharge light sources that have certain substantial drawbacks, including luminous efficiency and durability<10000 hours.

Since the fundamental discovery of the Japanese engineer S. Nakamura to provide a continuously operating laser diode (see Blue laser, Springer Verl. Berlin 1997), the history of high luminance semiconductor-based light sources and In—Ga—N oxide heterojunction having nano-scale quantum well architecture has been ten and more years. It substantially improves the electroluminescent efficiency of semiconductor. The modern light emitting devices that provide several tens or several hundreds of lumens are white LEDs. These LEDs are composed of two elements, i.e., the heterostructure and the light conversion layer. To green, green-yellow, or more particularly, blue-green devices, the unit luminous flux does not exceed by F=1 lm. Further, their efficiency is not over η=30˜45 lm/W (green color). To a blue-green radiator, the efficiency is smaller than η=20 lm/W. The physical reason of low luminous efficiency of an In—Ga—N heterostructure blue-green light emitting device has a great concern with high injection current value and low external radiation output (not greater than 40%) of green heterostructure.

More than 30 years ago, Russian engineers had introduced the preparation of GaN oxide heterosturcture-based two-element light emitting diode (see V Bramov, <<Light source with multiple elements>>, Creator Publishing Company, USSR N635813 Sep. 12, 1977). They teached the use of a Stokes inorganic phosphor-based conversion layer to cover a GaN oxide heterosturcture (Anti-Stokes phosphors for LED up-conversion were well known at that time (see Perg's <<Era of Light Emitting Diode>>, World Publishing Company, USSR, 1972). This legal document has been referred to in the present invention. According to this reference object, various types of inorganic Stokes phosphors are activated by the first order GaN heterostructure. Comparison of the emission spectrum of the heterostructure and the activation spectrum of the inorganic phosphors show a Stokes displacement value toward long wave radiation Δ=100˜150 nm.

The two-element composite LED with Stokes phosphor disclosed in V. Bramov's <<Light source with multiple elements>>is practical for generating a radiation of any spectrum composition. However, the cited reference still has substantial drawbacks: At the first place, the first order radiator of gallium nitride (GaN) has low efficiency; at the second place, the light emission in mid 20^{th} century is based on IIB VIA (ZnS—CdS-series) compound semiconductor phosphor and special materials of Zn₂SiO₄ or Ba₂SiO₄, i.e., it has many limits.

After 20 years in development, two-element composite white LED was created (see S. Schimizus U.S. Pat. No. 6,614,179). In the LED, In—Ga—N short wave heterostructure radiates at 450˜475 nm, activating the second order (Y,Gd,Ce)₃Al₅O₁₂ inorganic phosphor to produce light. By means of maintaining the unsaturated blue luminance of the first order heterostructure to mix with the yellow radiation of the phosphor, white radiations of different color tone (cold color, sunny color, warm color) are successfully obtained.

The concept of creation of two-element composite LED and green LED was introduced in V. Bramov's <<Light source with multiple elements)>, and adopted in S. Schimizu's U.S. Pat. No. 6,614,179 (see A. Srivastava's US Publication No. 2005-242327). Subject to these papers, an In—Ga—N short wave heterostructure-based green light source is prepared, and a light conversion layer for the heterostructure is created. This conversion layer is made in the form of a polymer film located on the radiation surface of the heterostructure and the optical contact at the end face. This thin film is filled with a dispersed phosphor powder. In a recent patent application filed by the present inventor, a compound of MeO×Me₂O₃ or 2MeO×MeO₂ is used, and activated by a rare earth element Eu⁺². This ion assures green radiation of the phosphor, and is suitable for LED. Same as the aforesaid patented prime model, this known architecture is easy to fabricate.

However, the aforesaid prime model has substantial drawbacks, and is not practical for wide application. One possible reason of the drawbacks is that the SrAl₂O₄:Eu or Ba₂SiO₄:Eu based inorganic phosphor has low efficiency. Further, it is to be understood that the preparation process of these materials is not perfect. Therefore, the aforesaid prime model was not utilized in the early LED fabrication.

### SUMMARY OF THE INVENTION

The present invention has been accomplished under the circumstances in view. It is therefore the main object of the present invention to provide a blue-green LED, which has high brightness and high-saturation chromaticity.

It is another object of the present invention to provide a blue-green LED, which greatly improves the optical parameters, and has relatively higher luminous intensity, higher luminous efficiency and higher luminous flux when compared to an In—Ga—N semiconductor heterostructure.

It is still another object of the present invention to provide a blue-green LED, which has high durability. It is still another object of the present invention to provide a phosphor for blue-green LED, which is practical for use to make a blue-green LED having high luminous efficiency, high brightness and high thermal stability.

To achieve these and other objects of the present invention, a blue-green LED comprises an In—Ga—N semiconductor heterostructure, and a light-converting layer formed of a thermosetting polymer layer and an inorganic phosphor having a long wave Stokes radiation displacement characteristic and covered on the In—Ga—N semiconductor heterostructure, wherein the In—Ga—N semiconductor heterostructure emits a first wavelength light at near ultraviolet region, and the light-converting layer emits a strong radiation to convert said first wave light into a second wavelength light.

To achieve these and other objects of the present invention, a phosphor used in a blue-green light-emitting diode comprises activators Eu⁺², Ce⁺³ and Pr⁺³ and a barium silicate-based substrate to make up the deficiency of Lu⁺³ and Li⁺¹ ions, having the stoichiometric equation: Ba_{2-x-y-z}(ΣTR)ₓLi_{y}Ln_{z}SiO₄wherein 0.01≦x≦0.08, 0.001≦y≦0.005, 0.001≦z≦0.01, Ln═Y and/or Gd and/or Lu and/or La.

### DETAILED DESCRIPTION OF THE PREFERRED EMBODIMENT

At first, the objective of the present invention is to eliminate the drawbacks of the aforesaid prior art phosphor and blue-green light-emitting diode. A blue-green light-emitting diode in accordance with the present invention comprises an In—Ga—N semiconductor heterostructure, and a light-converting layer formed of a thermosetting polymer layer and an inorganic phosphor having a long wave Stokes radiation displacement characteristic and covered on the In—Ga—N semiconductor heterostructure, characterized in that the In—Ga—N semiconductor heterostructure emits a first wavelength light at near ultraviolet region and the light-converting layer emits strong radiation to convert the first wave light into a second wavelength light;

wherein the first wavelength light has a wavelength λ=375˜405 nm;

wherein the second wavelength light has a wavelength λ=505˜515 nm, Stokes displacement 135˜105 nm, color coordinates 0.15<x≦0.22, 0.55<y≦0.60, width of half-wave of spectrum curveΔλ≦60 nm, and afterglow duration smaller than 100 ns;

wherein the phosphor is an inorganic phosphor comprising a substrate prepared from barium silicate containing activating elements Eu⁺², Ce⁺³ and Pr⁺³ to make up the deficiency of Lu⁺³ and Li⁺¹ ions, having the stoichiometric equation:

Ba_{2-x-y-z}(ΣTR)ₓLi_{y}Ln_{z}SiO₄;

wherein the index of the stoichiometric equation is 0.01≦x≦0.08, 0.001≦y≦0.005, 0.001≦z≦0.01, Ln═Y and/or Gd and/or Lu and/or La, ΣTR═Ce⁺³+Pr⁺³+Eu⁺²;

wherein the concentration of the activation elements in the substrate of the phosphor is: 0.5≦Eu⁺²/ΣTR≦0.75; 0.25<Ce⁺³/ΣTR≦0.45; and 0.001<Pr⁺³/ΣTR≦0.005;

wherein the inorganic phosphor has green reflective spectrum and a cubic crystal architecture of average size d_{cp}=4.0˜6.0 μm, d₁₀≦0.8 μm and d₉₀≦8 μm;

wherein the phosphor has the surface thereof covered with a δ=50 nm nano-scale Ba₃(PO₄)₂ thin film.

The physical-chemical features of the present invention will be described hereinafter. The following table I shows comparison data of a blue-green single-element composite light-emitting diode and a blue-green two-element composite light-emitting diode.

TABLE I

| | In—Ga—N | |
|---|---|---|
| | heterostructure | LED of heterostructure |
| | single-element composite | with phosphor of |
| Parameters | LED | two-element composite |
| Colorλₘₐₓ, nm | Blue-green 505~530 nm | Blue-green |
| | | 505~530 nm |
| Color coordinates | x = 0.12 | x = 0.17 ± 0.08 |
| | y = 0.48 | y = 0.55 ± 0.08 |
| Max. Value half-wave | 30~32 | 60~65 |
| wdith, nm | | |
| Afterglow duration, ns | 10 | 100 |
| Half-value angle | 1 | >10 |
| 2θ = 60° | | |
| luminous intensity, cd | | |
| Flux | 0.1~0.5 | 2~8 |

From the data shown in Table I, we can obtain the conclusion: the radiation color coordinates of the two-element composite LED is in the blue-green region; In—Ga—N LED injection electroluminescence has a narrow emission spectrum Δλ_{0.5}=30˜32 nm; at this time the total radiation of the two-element composite LED has a doubled spectrum half-wave width Δλ_{0.5}□62 nm; single-element composite LED has a short afterglow duration and its radiation is extinguished within 10˜20 ns after termination of activation, and this parameter in the two-element composite LED is determined subject to the parameters of the phosphor to be T_{y}□100 ns.

The radiation efficiency of single-element composite LED heterostructure does not exceed by 40% that is because the material has a high reflective index n≈2.8. A two-element composite LED has a relatively higher external radiation efficiency and its phosphor has a relatively smaller reflective index n≈1.70. These external radiation efficiency values assure the parameter value, for example, luminous intensity J (cd). In a single-element green LED, the half-value angle is 2θ=60°, this parameter value is J=1 cd, and at this time the luminous intensity of a two-element composite LED is greatly enhanced and cansurpass J□10 cd.

The external radiation efficiency determines the flux value of the LED. To a standard blue-green LED, the flux value is small, and the working current I=30 mA, normally 0.51 m. The flux value of a two-element composite LED is substantially higher than its effective luminous flux, as indicated, to be F=2˜8 lm. When LED high working power W=0.05˜0.2 watt, the said luminous flux value is achievable.

The aforesaid advantages are seen in a nitride heterostructure-based blue-green LED provided by the present invention, which is characterized in that: the polymer film layer that is covered over all the radiation prism and end face of the heterostructure contains by weight 12˜30% inorganic phosphor powder, forming a spectrum conversion layer to effectively absorb the first short wave radiation of the heterostructure and to perform a Stokes displacement toward the longer wavelength of blue-green region Δ□150 nm

Under the examination of a professional instrument from <<Sensing>>, the related light technology parameters of the LED provided by the present invention are assured and introduced in the following Table II.

| | | | Intensity | Half-wave | |
|---|---|---|---|---|---|
| | J, mA | V(V) | (mcd) | angle 2θ | Flux |
| 1 | 20 | 3.5 | 21000 | 60 | 5 lm |
| 2 | 40 | 3.47 | 42000 | 60 | 11 lm |
| 3 | 60 | 3.52 | 58000 | 60 | 17.8 lm |
| 4 | 80 | 3.6 | 76000 | 60 | 20 lm |
| 5 | 100 | 3.62 | 89000 | 60 | 24.4 lm |

Wherein, the chromaticity coordinates: x₁=0.2000, y₁=0.5900; x₂=0.2100, y₂=0.6150; x₃=0.24, y₃=0.625; x₄=0.255, y₄=0.635. Table II provides luminous flux value of the powder of the blue-green heterostructure to be 12 lm or higher when activation power is W=0.21 watt. To blue-green radiation band, this luminous flux value is quite high. This value is not seen in product brushures of most known LED manufactuers. The luminous flux value also indicates another characteristic of the LED provided by the present invention, i.e., high luminous efficiency value. When activation power W=0.21 watt, a modified model of the LED provided by the present invention shows a luminous efficiency η>65 lm/w. An In—Ga—N based single-element composite LED does not have such a high luminous efficiency value (see www.nichia.com 10.07.2007). The aforesaid advantages are seen in the blue-green LED provided by the present invention that is characterized in that: when half-value angle 2θ=60°, current J=30 mA, thus radiation luminous intensity 20□1□40 cd, device radiation total luminous flux F□6 lm; when device power W=0.1˜0.25 watt, the luminous efficiency value η>65 lm/W.

The above description analyzed the properties of the blue-green LED provided by the present invention. The above description analyzed the properties of the blue-green LED provided by the present invention. The spectrum-optical characteristics of the blue-green LED are determined subject to the properties of the composed inorganic phosphor collector: luminous color and radiation peak wavelength λₘₐₓ, 1931 CIE (Commision international of illumination) system radiation color coordinates x, y, spectrum maximum value half-wave width λ_{0.5} and radiation domant wavelenth λₘₐᵢₙ, and radiation afterglow duration (Tₑ). To eliminate the drawbacks of the first order radiator during the experiment, certain important optical conditions must be fulfilled: 1. Compare the maximum value of the excitation spectrum of the second conversion radiator-phosphor and the maximum value of the emission spectrum of In—Ga—N compound semiconductor heterostructure; and 2. Enhance the optical concentration of the spectrum conversion layer, and analyze the possible extreme values of the external first order radiation at the optical contact and the heterostructure.

The important optical requirements of the LED architecture provided by the present invention and the spectral characteristics of the optical conversion layer of the LED architecture are discussed hereinafter. The conversion layer is comprised of a polymer adhesive and an inorganic phosphor. At first, the emission spectrum of In—Ga—N heterostructure and the excitation spectrum of the phosphor used must be harmonized. The results of various different orders of radiation materials have been well described (see <<Comparison on properties of different types of phosphors for white LED>>, page 59˜61 with respect to Ga, In, Al nitride, the 5th International Conference 31, 01, 2007 Moscow university, Moscow). The excitation spectrum of the luminance of silicate phosphor has two spectrum maximum values. One spectrum maximum value is distributed in the near ultraviolet shortwave band λ=375˜405 nm. At this time, the second spectrum maximum value is in the blue region in the wavelength band λ=440˜475 nm. Shortwave distribution has a great concern with the internal structure of the phosphor lattice. In the known patented Ba₂SiO₄ based phosphor, the lattice has a complicated SiO₄ “skeleton”, and coordinated around the major cation Ba⁺², forming a strong chemical bond Ba—O—Si. The compound space group forms a cubic lattice. The coordinate number of Ba⁺² is K and B. The 6S² electron pair of Ba atom passes through Ba—O bond and is directly transited to O⁻²2 p track. This chemical bond energy is E=3˜3.5 ev, and determined subject to the first spectrum maximum value.

The second spectrum maximum value of silicate phosphor has a great concern with the energy band of the activator, and is determined subject to lowering of the energy level of the surrounding activator Eu⁺² around oxygen-silicate. The Europium ion has two degrees of oxydation: Eu⁺² and Eu⁺³. The first characteristic is that the external electron 6S² causes the internal ions of oxygen ion to transit to 4f⁶. The second degree of oxydation Eu⁺² forms stable 4f⁷ in the internal track of 4f⁶, and one half of the electrons filled is in f-track. This composition is quite stable. Its presence has a great concern with Europium ion and a big amount of electrons-abundant S⁻², Cl⁻¹, Br⁻¹ and O⁻². With respect to the ion-contributor, 4f⁷ electron structure causes an insufficient partial transition, thereby producing the so-called “charge unbalanced energy band”, indicated by Eu⁻²←O⁻² or Eu⁻²←S⁻². The temporary damage of this energy band forms the ion monomer Eu⁺² that consumes a certain of energy, normally E=2.8˜3.2 ev. Therefore, the second maximum value activated by the radiation of the barium silicate-based phosphor is determined subject to energy bonding or separation of the two atoms Eu⁻²←O⁻², and this maximum value is at λ=440˜460 nm blue band. The intensity ration of these maximum values is variable without relying upon the synthesis conditions of the silicate phosphor. Thus, the reduction of oxygen that represents the second activation maximum value is higher than the first (short wave) maximum value. During preparation of the phosphor, the long wave activation intensity in CO/CO₂ is lowered, at this time the phosphor is activated by ultraviolet light.

We noted that the In—Ga—N system used in the LED provided by the present invention has two spectrum heterostructures, i.e., ultraviolet band and blue band radiations. Further, the two different heterostructure spectrum activate phosphors of the same chemical composition.

According to phosphor chemical composition, the phosphors used in green LEDs include the following types, oxygen contained silicate, such as Me₂SiO₄TR⁺², and gadolinium contained silicate, such as SrGa₂S₄:TR⁺². The element Eu⁺² of which the degree of oxydation +2 is used as activator. The main characteristics of phosphors provided by the present invention have been fully studied (see <<Comparison on properties of different types of phosphors for white LED>>, page 59˜61 with respect to Ga, In, Al nitride, the 5th International Conference 31, 01, 2007 Moscow university, Moscow). These phosphors have been intensively used in LEDs. However, they still have certain substantial drawbacks. These phosphors have a complicated composition. Further, they use expensive Ga₂O₃ during synthesis. A silicate phosphor of the equation Me₂SiO₄TR⁺ has the major drawback of insufficient luminous brightness. According to our several measurements, Ba₂SiO₄:Eu⁺² phosphor has a luminous brightness about L=50˜55. 10³ units. When compared to a LED provided by the present invention, this luminous brightness value is relatively lower.

To overcome the major drawback of the known Ba₂SiO₄:Eu⁺² phosphor, the invention provides a phosphor for blue-green LED, which uses Eu⁺², Ce⁺³, Pr⁺³ as activators and barium silicate as the substrate to make up the deficiency of Lu⁺³ and Li⁺¹ ions, having the stoichiometric equation: Ba_{2-x-y-z}(ΣTR)ₓLi_{y}Ln_{z}SiO₄, wherein 0.01≦x≦0.08, 0.001≦y≦0.005, 0.001≦z≦0.01, Ln═Y and/or Gd and/or Lu and/or La. Unlike Ba₂SiO₄:Eu⁺² phosphor to be activated by a rare earth element, the phosphor provided by the present invention is an inorganic phosphor, characterized in that the phosphor powder has green reflective spectrum and a cubis crystal architecture, and the average particle size of d_{cp}=4.0˜6.0 μm, d₁₀≦0.8 μm and d₉₀≦8 μm. Further, the phosphor has the surface thereof covered with a layer of δ=50 nm nano-scale Ba₃(PO₄)₂ thin film.

Unlike the prime model phosphor that uses Ba₂SiO₄, the phosphor provided by the present invention is activated by three activators, Eu⁺², Ce⁺³ and Pr⁺³. Because the activator substrate has ions +2(Eu⁺²) and +3(Ce⁺³ and Pr⁺³) therein, Ln═Y and/or Gd and/or La and/or Lu ions are added for the lattice cations. Because the size of Ce⁺³ is small, it can enter the lattice more easily than other ions.

At this time, the ions in the lattice can be described as:

Ba_{Ba}+Ce⁺³→(Ce_{Ba})^{o}+Ba⁺²

Ba_{Ba}+Li⁺¹→(Li_{Ba})′+Ba⁺²

The amount that entered the substrate is within the range of 0.01□x□0.08 atomic fraction. The supplementary Ln series ions is 0.0001□Ln□0.01 atomic fraction. The concentration of Li⁺¹ in the phosphor substrate is 0.001□y□0.005. According to all the elements added, the stoichiometric equation of the silicate phosphor is recorded as Ba_{2-x-y-z}(ΣTR)ₓ(Li)_{y}(Ln)_{z}SiO₄; the number of oxygen ion in the anion lattice can be not equal to 4, i.e., [O]=4±δ, wherein 0.0001□δ□0.02. Unlike the known Ba₂SiO₄:Eu⁺² phosphor, the phosphor provided by the present invention has the following reatures: 1. The phosphor has added thereto activators of different degrees of oxydation, i.e., Eu⁺², Ce⁺³ and Pr⁺³; 2. There are added to the phosphor substrate, ion pairs selected from group-I elements Li⁺, and group-III ions of rare earth elements Ln═Y and/of Gd and/or Ln and/or La; and 3. Sr⁺² filler of concentration [Sr]≦0.3 atomic fraction is used to achieve long wave spectrum displacement.

All the differences in the phosphor compositions provided by the present ivnention show excellent properties of the phosphor. At first, the luminous intensity of the phosphor provided by the present invention is enhanced. The luminous intensity enhancement data can be seen in the attached spectroradiometric analysis reports of Annex 1, 2 and 3. Annex 1 is a spectroradiometric analysis report made on a (Ba₁₋ₓEuₓ)₂SiO₄ phosphor sample. Annex 2 is a spectroradiometric analysis report made on a (Ba_{1-x-y-z}EuₓCe_{y}Pr_{z})₂SiO_{4±δ} phosphor sample provided by the present invention. Annex 3 is a spectroradiometric analysis report made on a [Ba_{1-x-y-z-p-q}EuₓCe_{y}Pr_{z}LiₚLu_{q}]₂SiO_{4±δ} phosphor sample provided by the present invention, in which the stoichiometric index for activators Eu⁺², Ce⁺³ and Pr⁺³ is x=0.022, y=0.012, z=0.001, and under this condition, the charge compensation is [Li]□10.002, [Lu]=0.002.

When compared to the standard (Ba_{0.975}Eu_{0.025})₂SiO₄ phosphor of which the radiation intensity L=66410 units (see Annex 1), [Ba_{0.97}Eu_{0.023}Ce_{0.005}Pr_{0.002}]₂SiO_{4±δ} phosphor has the luminous intensity increased to L=99314 units (see Annex 2).

When charge compensation (Li_{Ba}) ion and Gd series (Gd_{Ba})^{o} ion are added to the phosphor provided by the present invention, the radiation efficiency is doubled and reaches 115000 units when comapred to the first standard [Ba_{0.98}Eu_{0.025}]₂SiO₄ (see Annex 3). These substantial changes in phosphor performance are determined subject to that the barium silicate substrate phosphor contains not only one activator. Actually, the phosphor contains three activators ΣTR=Pr⁺³+Eu⁺²+Ce⁺³, having the concentration: 0.5≦Eu⁺²/ΣTR≦0.75; 0.25≦Ce⁺³/ΣTR≦0.45; 0.001<Pr/ΣTR≦0.005, at the total concentration: ΣTR≦0.025.

To prepare the proposed blue-green phosphor, solid phase synthesis is adoped. Carbonic ester, oxalate or barium hydroxide is used as the prime material and doped with silicon oxide. Active filler is added to the batch composition by means of HCOOH-salt coprecipitation. the material composition and the activefiller are blended. NH₄Cl is added to the batch composition, enabling the match to be well compacted during sythensis. The systhesis of the inorganic phosphor provided by the present invention does not have any supply of sulfide filler, completing the radiation characteristic of end product.

An example of the synthesis of the phosphor provided by the present invention is introduced hereinafter. Example: 0.098M barium carbonate, added with 0.02M coprecipitation oxide of Eu, Ce and Pr at mass concentration ratio 80:18:2, and then added with 0.05M silicon dioxide.

To achieve charge compensation, 0.1% lithium carbonate and 0.1% yttrium oxide (by mass) are added to the batch. The batch is ground in a planet ball mill for 0.5 hour, and then loaded in a V=50 ml crucible and heated in an electric stove (H₂:N₂=5:95) subject to a predetermined heating mode: 600□-1 hour, 900□-1 hour, 1200□-1 hour, thereafter stop heating and let it be cooled down naturally, and then unload the product from the crucible and clean the product with water. Thereafter, coat the phosphor powder thus obtained with (NH₄)H₂PO₄ solution. The barium phosphate thin film thus formed has a concentration δ=50 nm. The phosphor is then screened through a 600 meshes screen, and then the physical-chemical properties of the phosphor is measured through a light technology measuring process.

The following Table III introduces the parameter values of the phosphor provided by the present invention. The substrate of the phosphor is barium silicate, and the three activators of the phosphor are Eu⁺², Ce⁺³ and Pr⁺³.

TABLE III

| | | | | Luminous | |
|---|---|---|---|---|---|
| | | Color | λₘₐₓ | intensity | d_{cp}, |
| No | Chemical composition | coordinates | nm | relative unit | μm |
| 1 | (Ba_{1.92}Eu_{0.07}Ce_{0.005}Pr_{0.005})SiO₄LiY | 0.2655 | 519.9 | 99314 | 6.2 |
| | | 0.6294 | | | |
| 2 | (Ba_{1.94}Eu_{0.05}Ce_{0.008}Pr_{0.002})SiO₄LiGd | 0.1859 | 507.1 | 55077 | 6.0 |
| | | 0.5634 | | | |
| 3 | (Ba_{1.96}Eu_{0.03}Ce_{0.006}Pr_{0.004})SiO₄LiLu | 0.1878 | 508.6 | 59081 | 5.8 |
| | | 0.5783 | | | |
| 4 | (Ba_{1.97}Eu_{0.025}Ce_{0.003}Pr_{0.002})SiO_{4.02}LiLa | 0.2637 | 522.2 | 115328 | 4.8 |
| | | 0.6317 | | | |
| 5 | (Ba_{1.98}Eu_{0.01}Ce_{0.005}Pr_{0.005})SiO_{4.01}LiLu | 0.2169 | 516.2 | 75000 | 6.0 |
| | | 0.6182 | | | |
| 6 | (Ba_{1.98}Eu_{0.01}Ce_{0.001}Pr_{0.001})SiO_{4.02} | 0.1956 | 509.4 | 642300 | 5.9 |
| | | 0.2807 | | | |
| 7 | (Ba_{1.98}Eu_{0.02})SiO₄, standard | 0.2007 | 509.6 | 51000 | 10.0 |
| | | 0.5700 | | | |

From the data introduced in the above Table III, we can obtain the conclusion that the phosphor smaple provided by the present invention has a luminous intensity within the range of L=55077˜115328 units subject to the proportion of the main elements in the phosphor substrate, and the value of the half-wave width of the radiation spectrum curve of the phosphor Δ0.5=60˜59 nm. The luminous color of the phosphor changes from light blue-light green to blue-green, at the same time the color purity α=0.75 (the color purity of a standard Zn₂SiO₄ phosphorα=0.79). Further, the phosphor has a nano-scale Ba₃(PO₄)₂ thin film formed on its surface to prohibit powder bonding and sintering.

In conclusion, the blue-green LED and the related phosphor convert near ultraviolet radiation λ=375˜405 nm into λ=505˜515 nm luminance of which the Stokes displacement is 135˜105 nm, the color coordinates is within the range of 0.15<x≦0.22, 0.55<y≦0.60, and the spectrum curve half-wave width is Δλ≦60 nm. Therefore, the invention effectively eliminates the drawbacks of conventional blue-green LEDs and their related phosphors.

Although particular embodiments of the invention have been described in detail for purposes of illustration, various modifications and enhancements may be made without departing from the spirit and scope of the invention.

What is claimed is:

1. A blue-green light-emitting diode, comprising an In—Ga—N semiconductor heterostructure, and a light-converting layer formed of a thermosetting polymer layer and an inorganic phosphor having a long wave Stokes radiation displacement characteristic and covered on said In—Ga—N semiconductor heterostructure, wherein said In—Ga—N semiconductor heterostructure emits a first wavelength light at near ultraviolet region, said light-converting layer emits a strong radiation to convert said first wave light into a second wavelength light.

2. The blue-green light-emitting diode as claimed in claim 1, wherein said first wavelength light has a wavelength λ=375˜405 nm.

3. The blue-green light-emitting diode as claimed in claim 1, wherein said second wavelength light has a wavelength λ=505˜515 nm, Stokes displacement 135˜105 nm, color coordinates 0.15<x≦0.22, 0.55<y≦0.60, spectrum curve half-wave width Δλ≦60 nm, and afterglow duration smaller than 100 ns.

4. The blue-green light-emitting diode as claimed in claim 1, wherein said inorganic phosphor comprises a substrate prepared from barium silicate containing activating elements Eu⁺², Ce⁺³ and Pr+3 to make up the deficiency of Lu⁺³ and Li⁺¹ ions, having the stoichiometric equation: Ba_{2-x-y-z}(ΣTR)ₓLi_{y}Ln_{z}SiO₄.

5. The blue-green light-emitting diode as claimed in claim 4, wherein the index of said stoichiometric equation is 0.01≦x≦0.08, 0.001≦y≦0.005, 0.001≦z≦0.01, Ln═Y and/or Gd and/or Lu and/or La.,

6. The blue-green light-emitting diode as claimed in claim 4, wherein the concentration of the activation elements ΣTR═Ce⁺³+Pr⁺³+Eu⁺² in the substrate of said phosphor is: 0.5≦Eu⁺²/ΣTR≦0.75; 0.25<Ce⁺³/ΣTR≦0.45; and 0.001<Pr⁺³/ΣTR≦0.005.

7. The blue-green light-emitting diode as claimed in claim 4, wherein said inorganic phosphor has green reflective spectrum and a cubic crystal architecture of average size d_{cp}=4.0˜6.0 μm, d₁₀≦0.8 μm and d₉₀≦8 μm.

8. The blue-green light-emitting diode as claimed in claim 4, wherein said inorganic phosphor has the surface thereof covered with a δ=50 nm nano-scale Ba₃(PO₄)₂ thin film.

9. A phosphor used in a blue-green light-emitting diode, comprising activators Eu⁺², Ce⁺³ and Pr⁺³ and a barium silicate-based substrate to make up the deficiency of Ln⁺³ and Li⁺¹ ions, having the stoichiometric equation: Ba_{2-x-y-z}(ΣTR)ₓLi_{y}Ln_{z}SiO₄, wherein 0.01≦x≦0.08, 0.001≦y≦0.005, 0.001≦z≦0.01, Ln═Y and/or Gd and/or Lu and/or La.

10. The phosphor as claimed in claim 9, which is an inorganic phosphor, the concentration of the substrate activators ΣTR═Ce⁺³+Pr⁺³+Eu⁺² is 0.5≦Eu⁺²/ΣTR≦0.75, 0.25<Ce⁺³/ΣTR≦0.45, and 0.001<Pr⁺³/ΣTR≦0.005.

11. The phosphor as claimed in claim 9, wherein the phosphor powder has green reflective spectrum and a cubis crystal architecture, and the average particle size of d_{cp}=4.0˜6.0 μm, d₁₀≦0.8 μm and d₉₀≦8 μm.

12. The phosphor as claimed in claim 9, which has the surface thereof covered with a layer of δ=50 nm nano-scale Ba₃(PO₄)₂ thin film.
